(19) United States
(12) Patent Application Publication
(10) Pub. No.: US 2019/0057936 A1
(43) Pub. Date: Feb. 21, 2019

(54) TRANSMISSIVE COMPOSITE FILM FOR APPLICATION TO THE BACKSIDE OF A MICROELECTRONIC DEVICE

(71) Applicant: Intel Corporation, Santa Clara, CA (US)

(72) Inventors: Mohit GUPTA, Chandler, AZ (US); Mukul RENAVIKAR, Chandler, AZ (US)

(21) Appl. No.: 15/770,626

(22) PCT Filed: Dec. 18, 2015
(86) PCT No.: PCT/US2015/066916

§ 371 Date: Apr. 24, 2018

(51) Int. Cl. H01L 23/538; H01L 21/683; H01L 23/498; H01L 23/26; H01L 23/532; H01L 23/00

(52) U.S. Cl. CPC H01L 23/5383; H01L 21/6836; H01L 23/49833; H01L 23/26; H01L 23/53228; H01L 2224/13147; H01L 23/562; H01L 2224/04105; H01L 2924/3511; H01L 2924/3512; H01L 23/53271

(57) ABSTRACT

A transmissive composite film is described that may be applied to the backside of a microelectronic device, for example an integrated circuit die or a bridge. A microelectronic die package in one example has a substrate, an integrated circuit die attached and electrically connected to the substrate, the die having a front side with electrical attachments and a backside, and a composite film attached to a backside of the die, the composite film having a polymer base with nano-fillers to protect the backside of the die.

### FIELD

The present description relates to microelectronic die packaging and, in particular, to a film for application to the backside of a microelectronic die during fabrication.

### BACKGROUND

In the manufacture of microelectronic devices, such as processors, controllers, and memory, the desired structures are formed on a wafer. Individual dies are cut from the wafer and then sealed into a package. The package has an array of pins, pads, or lands that make contact with the rest of the device, typically through a socket or a printed circuit board to allow the die to be operated while within the package. Before packaging each die is tested to ensure that it has been manufactured and operates as intended. The dies may be tested while still part of the wafer or after dicing or both. After packaging, each package is tested to ensure that it has been manufactured correctly and operates as intended.

The demand for ever smaller devices has created a demand for smaller integrated circuit packages. One approach to reducing the package size is to reduce the size of the die. This increases the demand for thin dies. A thin die is formed on a thick wafer and then the backside of the wafer or the die is thinned after it is finished processing but before it is packaged. Thin dies are in increasing use in a wide range of applications such as stacked and embedded packages. Thin dies are more vulnerable to stresses. Backside chipping and die crack are a major problem during thin die processing and can render a die useless.

During the singulation process thinned wafers are prone to backside chipping due to the mechanical vibration from the saw process. The silicon substrate is very brittle so any scratches and chips can lead to cracks and cracks can lead to fractures that damage or destroy the die for use as an integrated circuit. As a result, the dies are inspected for cracks and chips after sawing and before packaging. In some cases, the dies may be inspected more than once before a package is completed.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a side view diagram of an exposed die flip-chip package according to an embodiment.

FIG. 2 is a side view diagram of a stacked wire bond package according to an embodiment.

FIG. 3 is a side view cross-sectional diagram of an multiple die package with an embedded bridge according to an embodiment.

FIG. 4 is a side view diagram of a composite film according to an embodiment.

FIG. 5 is a diagram of process stages for applying a composite film to a die backside according to an embodiment.

FIG. 6 is a block diagram of a computing device suitable for use with embodiments.

### DETAILED DESCRIPTION

A transparent die backside film is described that protects a die against scratching and cracking during assembly and handling processes. As a transparent film it also allows chips and cracks to be detected using existing optical inspection tools. Defective dies may be binned out before they are sent downstream and assembled. Overall product quality and manufacturing yield are improved, resulting in lower costs.

A microelectronic package is described that has a transparent composite film permanently attached to one side of the semiconductor die. The other side of the semiconductor die may be coupled to a substrate by a set of one or more interconnects. The transparent composite film reduces backside chipping and improves the die edge quality. The film also reduces warpage in thin dies. Because the film is transparent, it allows for crack inspections. The film may be used in many different package architectures. As a further simplification the film may be applied together with conventional dicing tape.

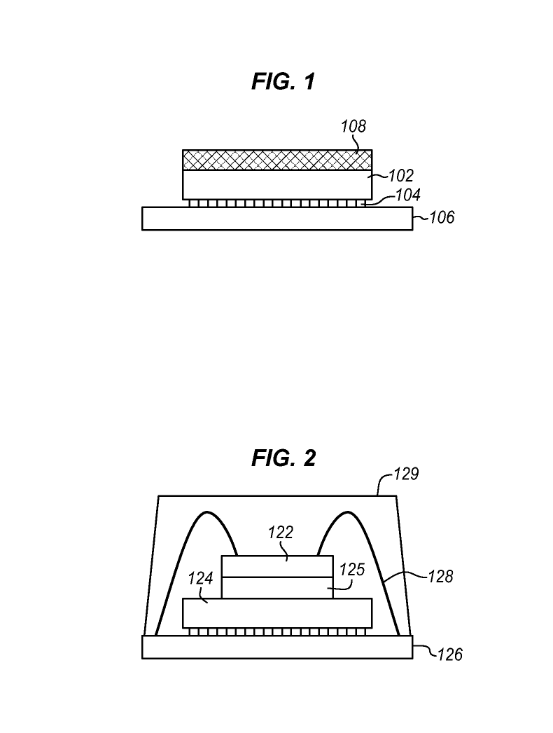

FIG. 1 is a side view diagram of an exposed die flip-chip package. An integrated circuit die 102 is attached to a package substrate 106 with an array of solder balls 104 to connect pads or lands on the front side of the die to corresponding pads or lands on the top side of the package. This connection is through solder joints so that the die is physically attached and electrically connected to the package. There may also be underfills, adhesives, or other materials to further secure the attachment of the die to the package. The package has an array of pads, lands or other connections (not shown) on the bottom side to allow the package to be attached to a socket or a printed circuit board, such as a motherboard, logic board, or system board. The backside of the die opposite the package has a transparent composite film 108, which may have been applied using a tape. The film is adhered to the backside of the die for protection during handling and is described in more detail below.

FIG. 2 is a side view diagram of a stacked wire bond package. This package has a top die 122 stacked over a bottom die 124. The bottom die 124 is attached to a package substrate 126 in the same or a similar way as in the example of FIG. 1. The top die has a backside facing and attached to the backside of the bottom die. The top side of the top die has lands or pads facing upward. Wire leads 128 are attached to the lands or pads of the top die front side at one end and attached to lands or pads on the top side of the package at the other end. In this way, the dies may be connected through the substrate. In this example, the top die is physically attached on its backside and electrically coupled through its front side.

The package is covered with an encapsulant, molding compound, or plastic cover 129. The cover protects the dies and the wire leads from contamination and physical movement. The cover may form a hermetic seal over the package. Similarly the die of FIG. 1 may also have a cover or be covered in an encapsulant, such as an epoxy resin.

A composite film 123 is on the backside of the bottom die 124 as in FIG. 1 and between the backside of the bottom die and the backside of the top die. Alternatively, the composite film is on the backside of the top die. The composite film may be applied to either one or both of the dies. As a result, there may a single or double layer of the film. The film protects the backs sides of the dies to which it has been attached. The film also has adhesive properties that hold the two dies together. It may also absorb mechanical forces between the two dies. These mechanical forces may be caused by acceleration such as drops and impacts and also by heating and cooling of the dies and the cover.

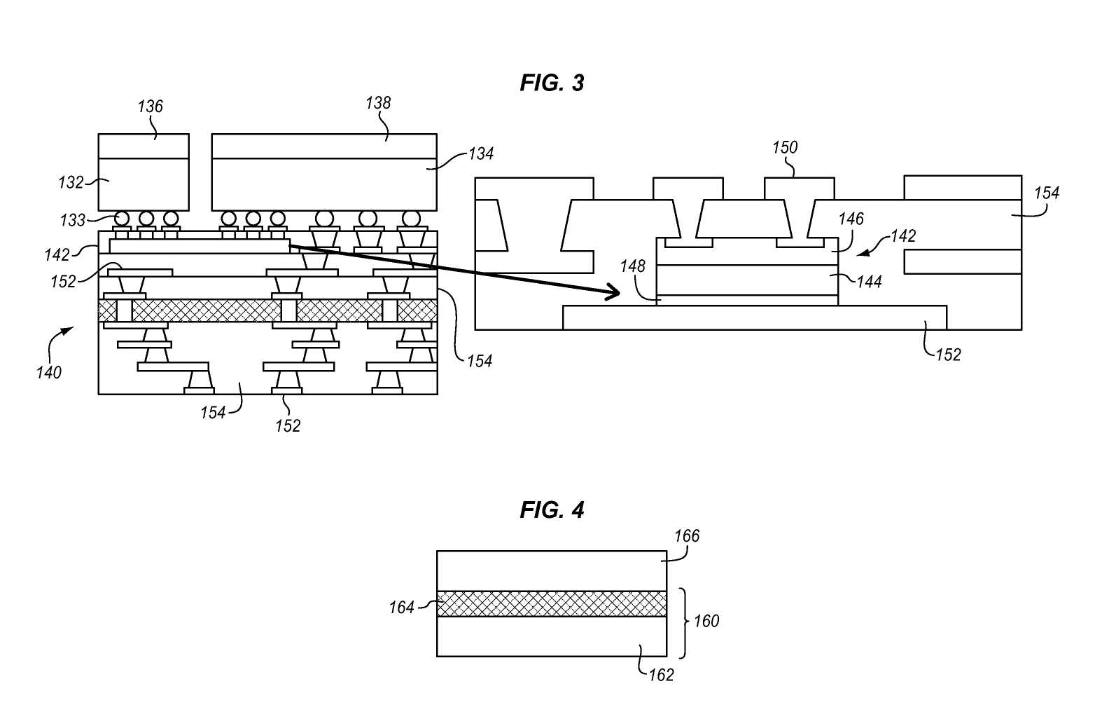

FIG. 3 is a side view cross-sectional diagram of an multiple die package with an embedded bridge such as an EMIB (Embedded Multi-die Interconnect Bridge) package. A first 132 and a second 134 die are attached to a substrate 140 using pads or lands and solder joints as in the example of FIGS. 1 and 2. A composite film 136, 138 may be applied to the backside of each of the dies for protection as described and shown above.

The package substrate 140 in this example may be formed of multiple layers of dielectric 154 with embedded conductive routing 152. This is shown as horizontal layers with vertical vias interconnecting them to allow for redistribution of the connections through the substrate layers. The top layer of vias provide connection for pads to connect to the dies. As shown in the enlarged view, a bridge 144 may be embedded within the substrate. The bridge may be formed of silicon in the same form as the integrated circuit die. Metal layers 146 are formed over the silicon for more precise redistribution and interconnection through vias 150 up to the dies. The bridge may also have a composite film 148 on one side opposite the connecting metal layers. This film may be used to attach the bridge to a metal layer 152 within the substrate as the substrate is formed. It also serves to protect the die during handling before it is embedded in the substrate.

FIG. 4 is a side view diagram of a composite film that may be used in the example package above and in many other types of packages. In this example, a composite film 164 is combined with a transparent dicing tape 160 to form a 2-in-1 tape that may be applied just as conventional dicing tape is applied. The dicing tape 160 has a base film 162 covered with an adhesive 164. The adhesive may or may not be released with ultraviolet light depending on the particular implementation. The base film may have a surface roughness in a sub-micron range to form a 2-in-1 tape that simplifies allows high transparency for surface roughness. With the composite film applied on the dicing tape. The combined combination structure may be used like dicing tape in processes that are already configured for use with a dicing tape.

The composite film 166 has a unique composition. It may be a polymer based composite material that contains nano-fillers. The fillers may be formed of any of a variety of different materials, including silica and may have an average filler size of less than 100 nm. For films for which thermal conductivity is also desired, then conductive fillers including metallic fillers such as copper, alumina, aluminum nitride, boron nitride, silicon carbide etc. may be added. Fillers typically have a low CTE (Coefficient of Thermal Expansion) whereas polymers typically have a high CTE. Fillers may therefore be used to reduce the overall CTE and therefore to reduce or lower the CTE mismatch between a Si die and the polymer film.

The composite film may also have a catalyst to promote curing. The polymer is thermally curable and the catalyst promotes cure at a lower temperature and a shorter amount of time. The catalyst may be a non-pigmented material so that the film maintains its transparency.

While the polymer and the catalyst are highly transmissive, the silica, metal or other filler materials may not be. In some embodiments, the composite film is sufficiently transmissive that the backside of the die can be inspected using visible or near infrared light. This provides further quality assurance because any dies that are damaged during handling can be inspected to ensure that they may still be used. A light transmission rate or transmissivity of greater than 60% in the visible and near infrared light range is obtained using the materials described herein. In some cases a transmissivity of greater than 80% may be obtained, depending on the type of filler and filler concentration or amount of filler loading.

The polymers allow the film to be tacky at temperatures over 50° C. to allow for easy wafer backside lamination and to allow for easy die attach for stacked or embedded packages. The film has excellent adhesion to silicon and once laminated on the wafer backside has a sufficiently high interfacial adhesion to minimize delamination risks during reliability stressing.

Using the mostly transparent nano-fillers, a high transparency is obtained. The nano-fillers also add strength so that the film provides a protective layer between the die and any external damage. The polymeric film provides protection against die scratches and cracks during the assembly and handling processes. There are many materials available to protect the backside of a die, but many of these materials are opaque and prevent the backside of the die from being inspected. If the film is compliant and intact, but the die is scratched or cracked, then the die may still be useless.

Because the composite film is transparent, the die backside covered with the composite film can be optically inspected through the film for chipping. Typical optical inspections use visible or near infrared light to illuminate the die and then analyze the reflection to find chips and cracks. Dies are typically singulated by sawing. For thin dies there is an especially high risk of cracking and the transparent composite film allows the die to be inspected for cracks and other defects after singulation and pick and place in a TnR (Tape and Reel). Early inspection allows dies to be sorted out before the additional costs of downstream assembly and reliability tests.

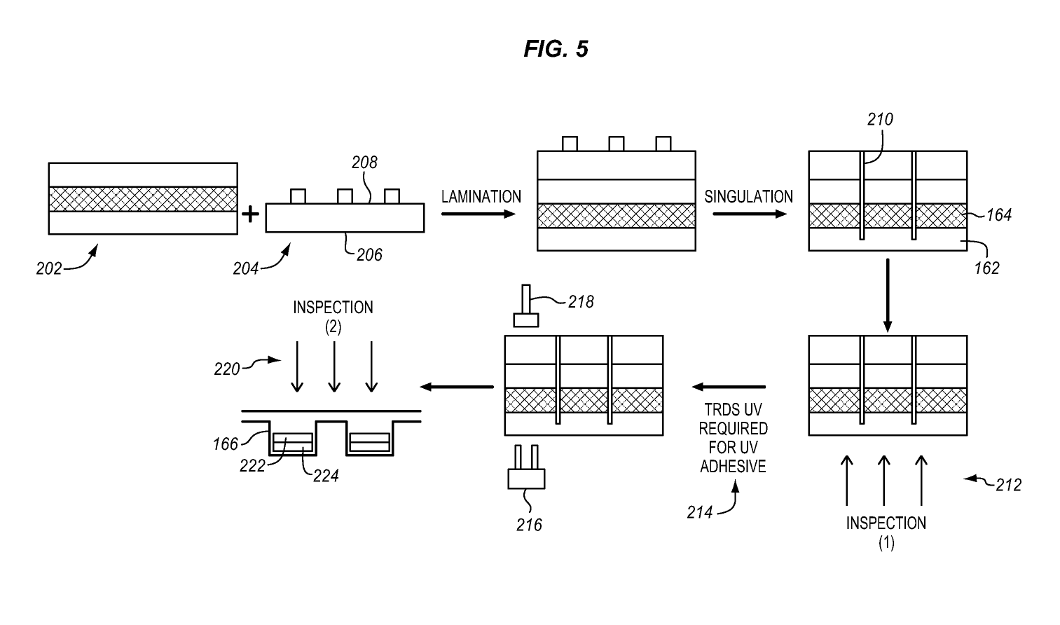

FIG. 5 is a diagram of possible process stages for using and applying the composite film described above. As mentioned above, the 2-in-1 tape may be applied to the backside of a wafer without any significant changes to some of the die preparation processes. Initially a composite film 202 is applied to a wafer 204. The wafer has a backside 206 and a front side 208 with active circuitry or conductive metal layers or another applied structure on the front side. The wafer may be thinned and other processes may also be applied. The combined structure is formed by laminating the film onto the backside of the die as shown. The particular approach for lamination may depend upon the type of adhesive in the composite film 166. In some embodiments, the tape or the wafer or both are heated and the tape is applied with pressure.

After laminating the tape on to the wafer backside, a saw blade cuts through the composite film forming kerfs 210 that extend through the wafer and the polymer film. In some cases, the kerf does not extend through the dicing tape base film so that the film holds the dies together for inspection. All of the dies of the wafer may then be inspected 212 as a single piece with the base film holding the wafer together.

The dies 222 resulting from singulation with the composite film 166 still attached are ejected from the dicing tape 160 and placed into a TnR (Tape and Reel) 224 for example for downstream assembly. The dies may be ejected using an ejector needle 216 and pick head 218. In some processes, the adhesive layer 164 is relaxed using ultraviolet light or other processes. Once placed in a tape 224 or trap backside up, the dies 222 can again be inspected 220 for cracks and other defects through the transparent polymer film. Alternatively, the dies may go from TnR to be attached directly over substrates or dies. In some cases the TnR is not used.

During the singulation process 210 thin dies are prone to backside chipping due to the mechanical vibration from the sawing process. The described composite polymer film material prevents damage from direct physical contact but may not be completely effective against vibration. The composite film also has very high clarity. As a result, the singulation lines are clearly visible along with any die chipping along the singulation lines. The visible lines may be used to estimate the chipping in thin dies, which can then be used to improve a singulation process to minimize the chipping. In addition, dies with excessive chipping can be binned out and prevented from being used in final packages because of their risk of failure.

The described composite polymer material is not only very clear but also has a high light transmission. The reflection from the die surface with the film attached is almost the same as for bare silicon. This helps in die crack detection using the existing inspection cameras. Partially cracked dies in stacked, embedded, and even bare die packages are prone to failure when stressed.

With the push for thinner dies and smaller package form factors, the risk of die cracks becomes greater. The backside composite film helps to reduce chipping, improves the die edge quality and reduces or eliminates losses associated with die scratches and cracking. In addition, inspection with conventional inspection tools allows chips and cracks to be seen before the dies are sent downstream in the fabrication process and assembled.

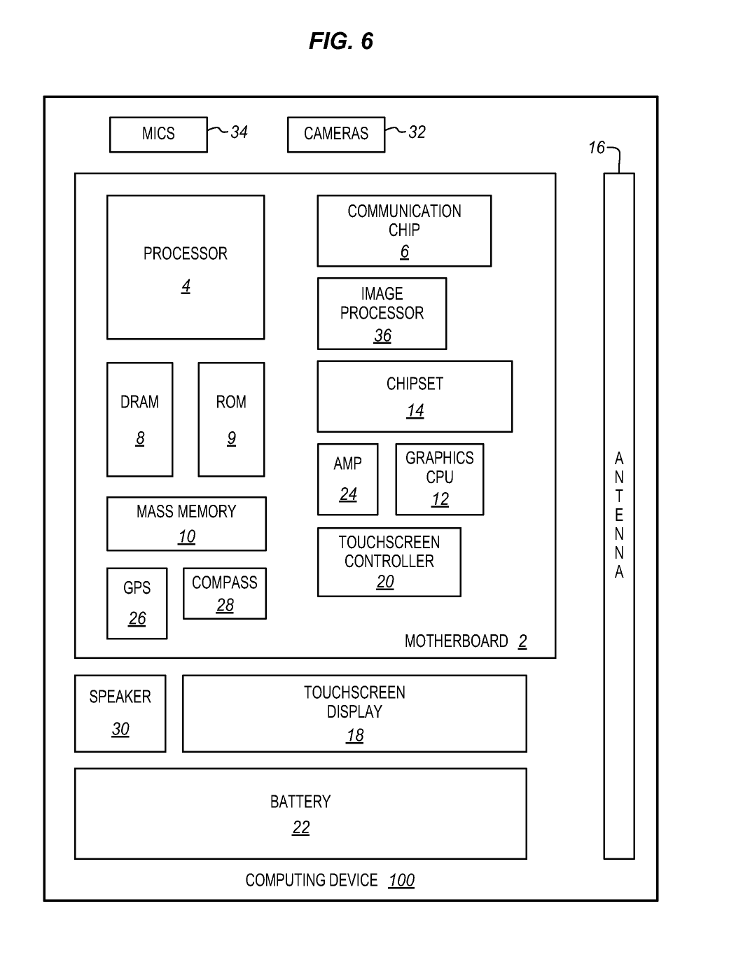

FIG. 6 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM) 508, non-volatile memory (e.g., ROM) 509, flash memory (not shown), a graphics processor 512, a digital signal processor (not shown), a crypto processor (not shown), a chipset 514, an antenna 516, a display 518 such as a touchscreen display, a touchscreen controller 520, a battery 522, an audio codec (not shown), a video codec (not shown), a power amplifier 524, a global positioning system (GPS) device 526, a compass 528, an accelerometer (not shown), a gyroscope (not shown), a speaker 530, a camera 532, and a mass storage device (such as hard disk drive) 510, compact disk (CD) (not shown), digital versatile disk (DVD) (not shown), and so forth). These components may be connected to the system board 502, mounted to the system board, or combined with any of the other components.

The communication chip 506 enables wireless and/or wired communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the packages that include the processor, memory devices, communication devices, or other components may be tested and assembled using a composite film as described herein, if desired. The term “processor” may refer to any device or portion of a device that processes electronic data from registers and/or memory to transform that electronic data into other electronic data that may be stored in registers and/or memory.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Embodiments may be adapted to be used with a variety of different types of packages for different implementations. References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, the specific location of elements as shown and described herein may be changed and are not limited to what is shown. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to a microelectronic die package that includes a substrate, an integrated circuit die attached and electrically connected to the substrate, the die having a front side with electrical attachments and a backside, and a composite film attached to a backside of the die, the composite film having a polymer base with nano-fillers to protect the backside of the die.

In further embodiments the fillers have an average size of less than 100 nm.

In further embodiments the fillers comprise silica.

In further embodiments the fillers comprises one or more of copper, alumina, aluminum nitride, boron nitride, and silicon carbide.

In further embodiments the fillers have a lower coefficient of thermal expansion than the polymer base to lower the coefficient of thermal expansion of the composite film.

In further embodiments the composite film has light transmissivity of more than 60%.

In further embodiments the film is tacky.

In further embodiments the composite film further comprises a non-pigmented catalyst.

Further embodiments include a second die over the first die and attached to the first die by the composite film.

In further embodiments the integrated circuit die is embedded in the substrate.

In further embodiments the front side is attached and electrically connected to the substrate.

Some embodiments pertain to a method that includes attaching a dicing tape to a back side of a wafer, the dicing tape having an composite film between an adhesive and the wafer, the composite film having a polymer base with nano-fillers to protect the back side of the wafer, dicing the wafer into singulated dies after attaching the dicing tape, removing the dicing tape without removing the composite film, inspecting the dies through the composite film, and packaging the dies without removing the composite film.

In further embodiments the composite layer nano-filler comprise silica.

In further embodiments removing the dicing tape comprises applying ultraviolet light to release the adhesive.

In further embodiments inspecting comprises optically inspecting using a camera.

In further embodiments packaging the dies comprises attaching the dies to a surface of a package using the composite film.

In further embodiments the surface comprises a package substrate, an embedded metal layer of a package substrate, or a backside surface of another die.

Some embodiments pertain to a computing system that includes a system board, a memory attached to the system board, a processor package attached to a substrate, the processor package having a processor die attached and electrically connected to the substrate, the die having a front side with electrical attachments and a backside, and a composite film attached to a backside of the die, the composite film having a polymer base with nano-fillers to protect the backside of the die.

In further embodiments the substrate has metal layers to electrically connect the processor to the system board, the processor package further comprising a bridge die embedded within the substrate to electrically connect metal layers of the substrate, the bridge having a layer of the composite film to attach the bridge to a metal layer.

Further embodiments include a second die over the processor die and attached to the processor die by the composite film.

1.-20. (canceled)

21. A microelectronic die package comprising:
a substrate;
an integrated circuit die attached and electrically connected to the substrate, the die having a front side with electrical attachments and a backside; and
a composite film attached to a backside of the die, the composite film having a polymer base with nano-fillers to protect the backside of the die.

22. The package of claim 21, wherein the fillers have an average size of less than 100 nm.

23. The package of claim 21, wherein the fillers comprise silica.

24. The package of claim 21, wherein the fillers comprises one or more of copper, alumina, aluminum nitride, boron nitride, and silicon carbide.

25. The package of claim 21, wherein the fillers have a higher coefficient of thermal expansion than the polymer base to increase the coefficient of thermal expansion of the composite film.

26. The package of claim 21, wherein the composite film has light transmissivity of more than 60%.

27. The package of claim 21, wherein the film is tacky.

28. The package of claim 21, wherein the composite film further comprises a non-pigmented catalyst.

29. The package of claim 21, further comprising a second die over the first die and attached to the first die by the composite film.

30. The package of claim 21, wherein the integrated circuit die is embedded in the substrate.

31. The package of claim 21, wherein the front side is attached and electrically connected to the substrate.

32. A method comprising:
attaching a dicing tape to a back side of a wafer, the dicing tape having an composite film between an adhesive and the wafer, the composite film having a polymer base with nano-fillers to protect the back side of the wafer;
dicing the wafer into singulated dies after attaching the dicing tape;
removing the dicing tape without removing the composite film;
inspecting the dies through the composite film; and
packaging the dies without removing the composite film.

33. The method of claim 32, wherein the composite layer nano-filler comprise silica.

34. The method of claim 32, wherein removing the dicing tape comprises applying ultraviolet light to release the adhesive.

35. The method of claim 32, wherein inspecting comprises optically inspecting using a camera.

36. The method of claim 32, wherein packaging the dies comprises attaching the dies to a surface of a package using the composite film.

37. The method of claim 36, wherein the surface comprises a package substrate, an embedded metal layer of a package substrate, or a backside surface of another die.

38. A computing system comprising;
a system board;
a memory attached to the system board; and
a processor package attached to a substrate, the processor package having a processor die attached and electrically connected to the substrate, the die having a front side with electrical attachments and a backside, and a composite film attached to a backside of the die, the composite film having a polymer base with nano-fillers to protect the backside of the die.

39. The computing system of claim 38, wherein the substrate has metal layers to electrically connect the processor to the system board, the processor package further comprising a bridge die embedded within the substrate to electrically connect metal layers of the substrate, the bridge having a layer of the composite film to attach the bridge to a metal layer.

40. The computing system of claim 38, the processor package further comprising a second die over the processor die and attached to the processor die by the composite film.
